(19) United States
(12) Patent Application Publication
(10) Pub. No.: US 2024/0258994 A1
(43) Pub. Date: Aug. 1, 2024

(54) ACOUSTIC WAVE DEVICE WITH INTERDIGITAL TRANSDUCER ELECTRODE HAVING SEED LAYER

(71) Applicant: Skyworks Solutions, Inc., Irvine, CA (US)

(72) Inventors: Kurt George Steiner, Orlando, FL (US); Alan Sangone Chen, Leesburg, FL (US); Yosuke Hamaoka, Suita-Shi (JP); Benjamin Paul Abbott, Irvine, CA (US); Michael David Hill, Emmitsburg, MD (US); Kezia Cheng, Lowell, MA (US)

(21) Appl. No.: 18/427,321

(22) Filed: Jan. 30, 2024

Related U.S. Application Data
(60) Provisional application No. 63/482,535, filed on Jan. 31, 2023.

(51) Int. Cl. H03H 9/25; H03H 9/02; H03H 9/64

(52) U.S. Cl. CPC H03H 9/25; H03H 9/02574; H03H 9/02834; H03H 9/6483

(57) ABSTRACT

An acoustic wave device is disclosed. The acoustic wave device can include a piezoelectric layer, and an interdigital transducer electrode formed with the piezoelectric layer. The interdigital transducer electrode includes a first layer, a second layer over the first layer, and a seed layer between the first layer and the piezoelectric layer. A combination of the first layer and the seed layer has a resistivity that is lower than a resistivity of the first layer alone.

### INCORPORATION BY REFERENCE TO ANY PRIORITY APPLICATIONS

Any and all applications for which a foreign or domestic priority claim is identified in the Application Data Sheet as filed with the present application, including U.S. Provisional Patent Application No. 63/482,535, filed Jan. 31, 2023, titled “ACOUSTIC WAVE DEVICE WITH INTERDIGITAL TRANSDUCER ELECTRODE HAVING SEED LAYER,” are hereby incorporated by reference under 37 CFR 1.57 in their entirety.

### BACKGROUND

### Technical Field

Embodiments of this disclosure relate to acoustic wave devices.

### Description of Related Technology

A surface acoustic wave filter can include a plurality of surface acoustic wave resonators arranged to filter a radio frequency signal. Each resonator can include a surface acoustic wave device. Example piezoelectric MEMS resonators include surface acoustic (SAW) resonators and temperature compensated surface acoustic wave (TC-SAW) resonators. A surface acoustic wave device can be configured to generate, for example, a Rayleigh mode surface acoustic wave in which the main mode of the acoustic wave generated by the surface acoustic wave device is Rayleigh mode, or a shear horizontal mode surface acoustic wave in which the main mode of the acoustic wave generated by the surface acoustic wave device is shear horizontal mode.

Surface acoustic wave filters can be implemented in radio frequency electronic systems. For instance, filters in a radio frequency front end of a mobile phone can include surface acoustic wave filters. A plurality of acoustic wave filters can be arranged as a multiplexer. For example, two surface acoustic wave filters can be arranged as a duplexer. Transverse leakage generally degrades the performance of the surface acoustic wave device.

### SUMMARY

The embodiments described in the claims each have several aspects, no single one of which is solely responsible for its desirable attributes. Without limiting the scope of the claims, some prominent features of this disclosure will now be briefly described.

In some aspects, the techniques described herein relate to an acoustic wave device including: a piezoelectric layer; and an interdigital transducer electrode formed with the piezoelectric layer, the interdigital transducer electrode including a first layer, a second layer over the first layer, and a seed layer between the first layer and the piezoelectric layer, a combination of the first layer and the seed layer having a resistivity lower than a resistivity of the first layer alone.

In some embodiments, the techniques described herein relate to an acoustic wave device wherein the first layer has a stiffness that is greater than a stiffness of the second layer.

In some embodiments, the techniques described herein relate to an acoustic wave device wherein the seed layer has a stiffness that is greater than a stiffness of the second layer.

In some embodiments, the techniques described herein relate to an acoustic wave device wherein the first layer and the seed layer include materials from the same group.

In some embodiments, the techniques described herein relate to an acoustic wave device wherein the first layer includes molybdenum, tungsten, or chromium, and the seed layer includes one of molybdenum, tungsten, or chromium not used for the first layer.

In some embodiments, the techniques described herein relate to an acoustic wave device wherein the first layer includes molybdenum, the second layer includes aluminum, and the seed layer includes tungsten.

In some embodiments, the techniques described herein relate to an acoustic wave device wherein the seed layer has a thickness in a range of 5 nm to 50 nm.

In some embodiments, the techniques described herein relate to an acoustic wave device wherein the seed layer has a thickness in a range of 5 nm to 20 nm.

In some embodiments, the techniques described herein relate to an acoustic wave device wherein the seed layer has a thickness less than 10% of a thickness of the first layer.

In some embodiments, the techniques described herein relate to an acoustic wave device wherein the seed layer has a thickness less than 5% of a total thickness of the interdigital transducer electrode.

In some aspects, the techniques described herein relate to an acoustic wave device including: a piezoelectric layer; and an interdigital transducer electrode formed with the piezoelectric layer, the interdigital transducer electrode including a first layer, a second layer over the first layer, and a tungsten seed layer between the first layer and the piezoelectric layer.

In some embodiments, the techniques described herein relate to an acoustic wave device wherein the first layer includes molybdenum.

In some embodiments, the techniques described herein relate to an acoustic wave device wherein the seed layer has a thickness in a range of 5 nm to 50 nm.

In some embodiments, the techniques described herein relate to an acoustic wave device wherein the seed layer has a thickness in a range of 5 nm to 20 nm.

In some embodiments, the techniques described herein relate to an acoustic wave device wherein the seed layer has a thickness less than 10% of a thickness of the first layer.

In some embodiments, the techniques described herein relate to an acoustic wave device wherein the seed layer has a thickness less than 5% of a total thickness of the interdigital transducer electrode.

In some aspects, the techniques described herein relate to an acoustic wave device configured to generate a surface acoustic wave having a wavelength L, the acoustic wave device including: a piezoelectric layer; and an interdigital transducer electrode formed with the piezoelectric layer, the interdigital transducer electrode including a first layer, a second layer over the first layer, and a seed layer between the first layer and the piezoelectric layer, the first layer having a first thickness in a range of 0.01 L to 0.075 L, the second layer having a second thickness in a range of 0.05 L to 0.2 L, and the seed layer having a third thickness in a range of 5 nm to 50 nm.

In some embodiments, the techniques described herein relate to an acoustic wave device wherein the first layer has a stiffness that is greater than a stiffness of the second layer.

In some embodiments, the techniques described herein relate to an acoustic wave device wherein the seed layer has a stiffness that is greater than a stiffness of the second layer.

In some embodiments, the techniques described herein relate to an acoustic wave device wherein the first layer and the seed layer include materials from the same group.

### BRIEF DESCRIPTION OF THE DRAWINGS

Embodiments of this disclosure will now be described, by way of non-limiting example, with reference to the accompanying drawings.

FIG. 1A is a schematic cross-sectional side view of a surface acoustic wave (SAW) device.

FIG. 1B is a schematic cross-sectional side view of a surface acoustic wave (SAW) device.

FIG. 2 is a graph showing simulated resistances (mΩ/sq) of a molybdenum layer and a combination of a tungsten seed layer and the molybdenum layer.

FIG. 3 is a graph showing simulated film stresses (MPa) of the molybdenum layer and the combination of the tungsten seed layer and the molybdenum layer relative to pressure (mbar).

FIG. 4A is a transmission electron microscopy (TEM) image of a cross-section of a molybdenum layer.

FIG. 4B is a TEM image of a cross-section of a molybdenum layer over a tungsten seed layer.

FIG. 5 is a graph showing resistivity values (μΩcm) of a molybdenum single layer and a combination of a molybdenum layer and a tungsten seed layer at various temperatures.

FIG. 6A is a schematic cross-sectional side view of a multilayer piezoelectric substrate (MPS) SAW device according to an embodiment.

FIG. 6B is a schematic cross-sectional side view of a temperature compensated surface acoustic wave (TC-SAW) device according to an embodiment.

FIG. 7A is a schematic diagram of a ladder filter that includes an acoustic wave resonator according to an embodiment.

FIG. 7B is a schematic diagram of a transmit filter that includes a surface acoustic wave resonator according to an embodiment.

FIG. 7C is a schematic diagram of a receive filter that includes a surface acoustic wave resonator according to an embodiment.

FIG. 8 is a schematic diagram of a radio frequency module that includes a surface acoustic wave component according to an embodiment.

FIG. 9 is a schematic diagram of a radio frequency module that includes filters with surface acoustic wave resonators according to an embodiment.

FIG. 10A is a schematic block diagram of a wireless communication device that includes a filter in accordance with one or more embodiments.

FIG. 10B is a schematic block diagram of another wireless communication device that includes a filter in accordance with one or more embodiments.

FIG. 11 is a schematic block diagram of a wireless communication device that includes a filter according to an embodiment.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Acoustic wave filters can filter radio frequency (RF) signals in a variety of applications, such as in an RF front end of a mobile phone. An acoustic wave filter can be implemented with surface acoustic wave (SAW) devices. The surface acoustic wave devices include, for example, SAW resonators, SAW delay lines, and multi-mode SAW (MMS) filters (e.g., double mode SAW (DMS) filters).

In general, high quality factor (Q), large effective electromechanical coupling coefficient or coupling factor (K²), high frequency ability, low resistivity, and spurious free can be significant aspects for micro resonators to enable low-loss (e.g., low-insertion loss) filters, stable oscillators, and sensitive sensors. Among other things, materials and physical structures of a SAW device can affect the performance of the SAW device.

In some SAW devices, an interdigital transducer (IDT) electrode can be a single layer IDT with a highly conductive material, such as aluminum (Al). In some other SAW devices, the IDT electrode can include a multilayer IDT electrode in which a combination of a highly conductive layer, such as an aluminum (Al) layer, and a high density layer that has a mass density greater than that of the highly conductive layer, such as a molybdenum (Mo) layer or a tungsten (W), can be used as the IDT electrode. The denser layer may reduce the acoustic velocity of acoustic waves travelling through the device which may allow the IDT electrode fingers to be spaced more closely for a given operating frequency and allow the SAW device to be reduced in size as compared to a similar device utilizing less dense IDT electrodes. However, the denser layer may have a higher resistivity that can negatively affect the performance of the SAW device. For example, a higher resistivity can cause greater loss in the SAW device.

Various embodiments disclosed herein relate to acoustic wave devices with a multilayer interdigital transducer (IDT) electrode having a seed layer. An acoustic wave device can include a piezoelectric layer and an interdigital transducer electrode formed with (e.g., formed on, over, in, or partially in) the piezoelectric layer. The interdigital transducer electrode can include a first layer, a second layer over the first layer, and a seed layer in contact with the first layer. The first layer and the seed layer can have stiffnesses that are greater than a stiffness of the second layer. The first layer and the seed layer can have mass densities that are greater than a mass density of the second layer. In some embodiments, the first layer can include molybdenum (Mo), the second layer can include aluminum (Al), and the seed layer can include tungsten (W). The first layer and the seed layer can have resistivities that is greater than a resistivity of the second layer. A combination of the first layer and the seed layer can have a resistivity that is less than the resistivity of the first layer alone and/or the resistivity of the seed layer along.

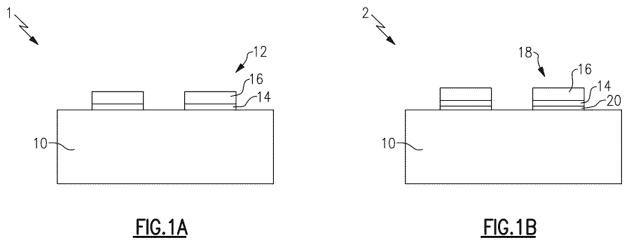

FIG. 1A is a schematic cross-sectional side view of a surface acoustic wave (SAW) device 1. The SAW device 1 can include a piezoelectric layer 10 and an interdigital transducer (IDT) electrode 12 formed with the piezoelectric layer 10. In the illustrated embodiment, the IDT electrode 12 is formed over (e.g., directly on) the piezoelectric layer 10.

The piezoelectric layer 10 can be a lithium tantalate (LT) layer or a lithium niobate (LN) layer. For example, the piezoelectric layer 10 can be an LT layer having a cut angle of 42° (42° Y-cut X-propagation LT) or a cut angle of 60° (60° Y-cut X-propagation LT). For example, the piezoelectric layer 10 can be 42±20° Y-cut LT, 42±15° Y-cut LT, 42±10° Y-cut LT, 42±5° Y-cut LT, 60±20° Y-cut LT, 60±15° Y-cut LT, 60±10° Y-cut LT, or 60±5° Y-cut LT. Any other suitable piezoelectric material, such as a lithium niobate (LN) layer, can be used as the piezoelectric layer 10. For example, the piezoelectric layer 10 can be an LN layer having a cut angle of about 118° (118° Y-cut X-propagation LN) or more or a cut angle of about 132° (132Y-cut X-propagation LN) or less. For example, the piezoelectric layer 26 can be 125±20° Y-cut LN, 125±15° Y-cut LN, 125±10° Y-cut LN, or 125±5° Y-cut LN. A skilled artisan will understand that, depending on the desired operation, the cut angles of the piezoelectric layer may be different from those listed above. A thickness of the piezoelectric layer 10 can be selected based on a wavelength A or L of a surface acoustic wave generated by the SAW device 1 in certain applications. The IDT electrode 12 has a pitch that sets the wavelength 2 or L of the SAW device 1. The piezoelectric layer 10 can be sufficiently thick to avoid significant frequency variation.

The IDT electrode 12 has a dual-layer structure that includes a first layer 14 and a second layer 16. The IDT electrode 12 can include any suitable material. For example, the first layer 14 can be tungsten (W) and the second layer 16 can be aluminum (Al) in certain embodiments. The IDT electrode 14 may include one or more other metals, such as copper (Cu), Magnesium (Mg), titanium (Ti), molybdenum (Mo), etc. The IDT electrode 12 may include alloys, such as AlMgCu, AlCu, etc.

As described above, inclusion of a relatively high density layer (e.g., the first layer 14) in the IDT electrode 12 can allow the SAW device 1 to be reduced in size as compared to a similar device utilizing less dense IDT electrodes or a single layer IDT electrodes. However, the denser layer may have a higher resistivity that can negatively affect the performance of the SAW device. Therefore, there is a drawback in using a multilayer IDT electrode that includes a material having relatively high resistivity.

FIG. 1B is a schematic cross-sectional side view of a surface acoustic wave (SAW) device 2. The SAW device 2 can include a piezoelectric layer 10 and an interdigital transducer (IDT) electrode 18 formed with (e.g., formed on, over, in, or partially in) the piezoelectric layer 10. In the illustrated embodiment, the IDT electrode 18 is formed over (e.g., directly on) the piezoelectric layer 10. Unless otherwise noted, components of FIG. 1B can be the same as or generally similar to the like components disclosed herein, such as those in FIG. 1A.

Unlike the IDT electrode 12 of the SAW device 1 shown in FIG. 1A, the IDT electrode 18 of the SAW device 2 shown in FIG. 1B includes a seed layer 20 in addition to a first layer 14 and a second layer 16. Although the IDT electrode 18 has a structure with three layers (the first layer 14, the second layer 16, and the seed layer 20) in the illustrated embodiments, any suitable principles and advantages disclosed herein can be applied to other IDT structures, such as an IDT electrode having only the first or the second layer 14, 16, and the seed layer 20, or multi-layer IDT electrodes that include more than the three layers.

In some embodiments, the first layer 14 and the seed layer 20 can have mass densities that are greater than a mass density of the second layer 16. In some embodiments, the first layer 14 and the seed layer 20 can have stiffnesses that are greater than a stiffness of the second layer 16. For example, the seed layer 20 can be the most dense and/or stiffest layer among the layers in the IDT electrode 18. For example, the first layer 14 can be a molybdenum (Mo) layer, the second layer 14 can be an aluminum (Al) layer, and the seed layer 20 can be a tungsten (W) layer. In some embodiments, the material of the seed layer can be selected based on the material of the first layer 14. For example, the seed layer 20 can be selected from the same or similar (a group closer to the material of the first layer 14 than to the material of the piezoelectric layer 10) group on the periodic table. For example, when the first layer 14 includes molybdenum (Mo), the seed layer can include a group 6 element (e.g., tungsten (W) or chromium (Cr)).

In some embodiments, depending on the desired operation, a thickness of the first layer 14 can be in a range from 0.01 L to 0.075 L and a thickness of the second layer 16 can be in a range from 0.05 L to 0.2 L. For example, when the wavelength L is 4 μm, the thickness of the first layer 14 can be about 40 nm to 300 nm and the thickness of the second layer 16 can be about 200 nm to 800 nm. A thickness of the seed layer 20 can be significantly thinner than the thicknesses of the first and second layers 14, 16. In some embodiments, the thickness of the seed layer 20 can be in a range of 5 nm to 50 nm, 5 nm to 40 nm, 5 nm to 30 nm, 5 nm to 20 nm, or 5 nm to 15 nm. In some embodiments, the thickness of the seed layer 20 can be less than 10%, less than 5%, or less than 3% of the thickness of the first layer 14. In some embodiments, the thickness of the seed layer 20 can be less than 10%, less than 5%, less than 3% or, less than 1% of the total thickness of the IDT electrode 18. The total thickness of the IDT electrode 18 may depend at least in part on the total mass of the IDT electrode 18.

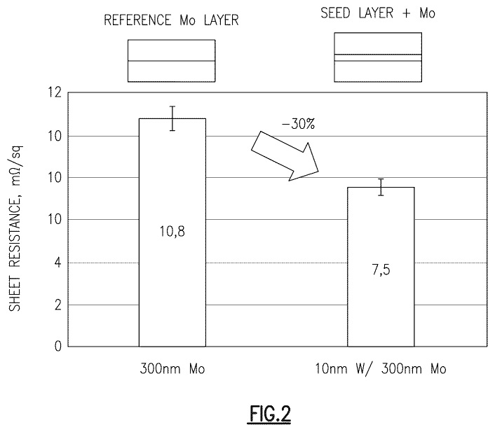

FIG. 2 is a graph showing simulated resistances (mΩ/sq) of a molybdenum (Mo) layer and a combination of a tungsten (W) seed layer and the Mo layer. In the simulations, the thickness of the Mo layer is set to 300 nm and the thickness of the W seed layer is set to 100 nm. The simulation results indicate that the combination of the W seed layer and the Mo layer can reduce the resistivity by about 30%. This finding was unexpected because the resistances of W alone and Mo alone are generally similar (Δresistance is within 2%; the resistance of Mo at 20° C. is 0.056 Ωmm²/m and the resistance of W at 20° C. is 0.055 Ωmm²/m).

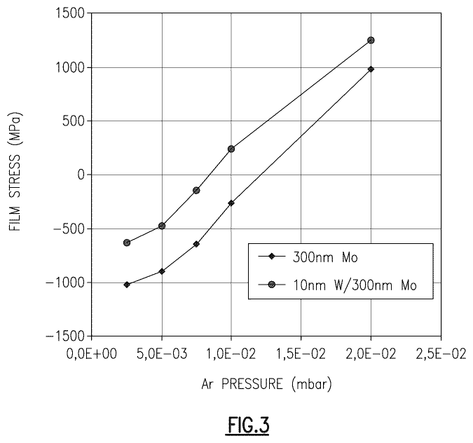

FIG. 3 is a graph showing simulated film stresses (MPa) of the Mo layer and the combination of the W seed layer and the Mo layer relative to pressure (mbar). The simulation results indicate that the film stress in the combination of the W seed layer and the Mo layer is more compressive than the film stress in the Mo layer alone. A skilled artisan will understand that based at least in part on conditions for forming the layer, the film stress can be adjusted. Such conditions can include deposition rate, pressure, or temperature. When a material is sputtered with a higher pressure, the compressive stress can be reduced, and the resulting layer or film may have a higher resistivity and a lower density. Annealing can decrease resistivity in some cases. For example, some materials (e.g., aluminum or molybdenum) may restructure after an annealing or baking process, and the grains within the material may grow. In some cases, the resistivity can drop by about 15% or more.

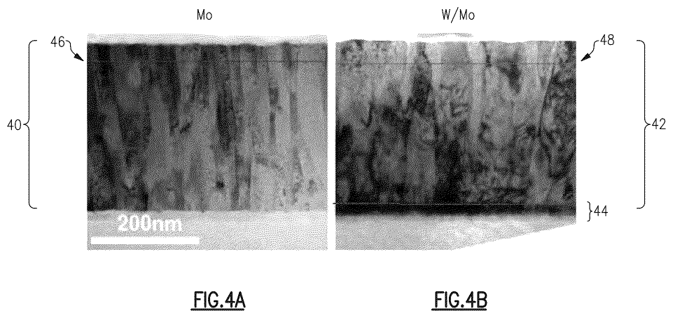

FIG. 4A is a transmission electron microscopy (TEM) image of a cross-section of a molybdenum (Mo) layer 40. FIG. 4B is a TEM image of a cross-section of a Mo layer 42 over a tungsten (W) seed layer 44. Widths of the grains in the Mo layers 40, 42 along lines 46, 48 are indicated in the images of FIGS. 4A and 4B.

Table 1 shown below includes average domain sizes based on x-ray diffraction measurements, lattice strains, and average lateral grain sizes based on the TEM images of the Mo layer 40 and the Mo layer 42 over the W seed layer 44.

TABLE 1

| | Coherently | | |
|---|---|---|---|
| | Diffracting | | Lateral Grain |
| | Domain Size | Lattice Strain | Size from TEM |
| | (nm) | (pm) | (nm) |
| Mo | 48.7 | 1.53 | 27.5 |
| Mo/W | 62.7 | 1.43 | 38.7 |

Table 1 indicates that the average domain size of the Mo layer 42 is increased by about 28% as compared to the Mo layer 40, the lattice strain in the Mo layer 42 is slightly decreased (−0.1 pm) as compared to the Mo layer 40, and the average lateral grain size of the Mo layer 42 is increased by about 40% as compared to the Mo layer 40.

The reduction in resistivity in the combination of the seed layer (e.g., the W seed layer) and a metal layer (e.g., the Mo layer) may be due, at least in part, to changes in the lattice strain, the texture of the layers, the grain size, and dislocations of grains in the layers. For example, because larger grains of a metal (e.g., Mo) are more stable than smaller grains of the metal, an IDT with grater grains can have lower resistivity than an IDT with smaller grains. Such correlation can be also indicated in a study that compares resistivities of a material at various deposition temperatures.

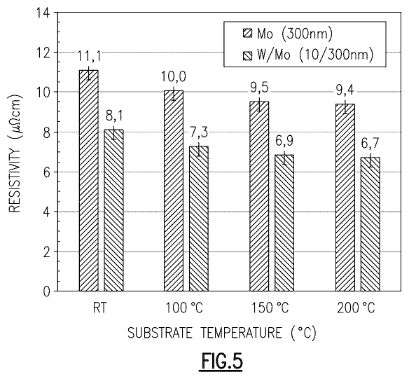

FIG. 5 is a graph showing resistivity values (μΩcm) of a Mo single layer and a combination of a Mo layer and a W seed layer at various temperatures. The Mo single layer has a thickness of 300 nm. The Mo layer and the W seed layer of the combination have thicknesses of 300 nm and 10 nm respectively. The graph of FIG. 5 shows that the resistivity decreases as the deposition temperature increases. It can be expected that the grains of the metals are greater when the deposition temperature is higher as the higher temperature can facilitate grain growth.

The graph of FIG. 5 show that the resistivity of the combination of the Mo layer and the W seed layer deposited at room temperature has is lower than the resistivity values of the Mo single layer deposited at room temperature, 100° C., 150° ° C., and 200° C., and the resistivity of the combination of the Mo layer and the W seed layer decreases as the deposition temperature increases. In some applications, the maximum deposition temperature may depend at least in part on the material used for the substrate to which the metal layers are deposited. For example, a piezoelectric layer, such as a lithium niobate (LN) layer or a lithium tantalate (LT) layer may be damaged when the deposition temperature is greater than about 200° C. or about 250° ° C. Also, as the thermal budget may increase as the deposition temperature increases, a relatively high temperature deposition may not be economically advantageous.

Thus, including the seed layer disclosed herein (e.g., the W seed layer) in an IDT electrode can provide a significantly lower resistivity without subjecting the IDT layers to a high temperature as compared to an IDT that does not include a seed layer. Accordingly, including the seed layer disclosed herein can enable manufacture of a relatively low-loss surface acoustic wave devices without damaging the piezoelectric layer to which the IDT is disposed.

The principles and advantages disclosed herein can be useful in various SAW devices. For example, the principles and advantages disclosed herein can be implemented in a multilayer piezoelectric substrate (MPS) SAW device, a temperature compensated surface acoustic wave (TC-SAW) device, a Lamb wave device, a shear horizontal mode acoustic wave device, or any acoustic wave devices that include an interdigital transducer electrode over a piezoelectric layer.

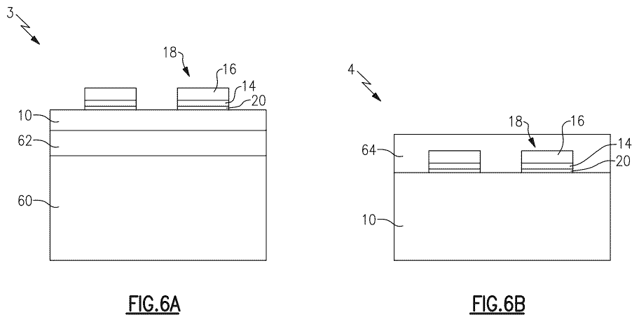

FIG. 6A is a schematic cross-sectional side view of a multilayer piezoelectric substrate (MPS) SAW device 3 according to an embodiment. FIG. 6B is a schematic cross-sectional side view of a temperature compensated surface acoustic wave (TC-SAW) device 4 according to an embodiment. Unless otherwise noted, components of FIGS. 6A and 6B can be the same as or generally similar to the like components disclosed herein, such as those in FIGS. 1A and 1B.

The MPS SAW device 3 can include a support layer 60, a piezoelectric layer 10 over the support substrate layer 60, an intermediate layer 62 between the support substrate 60 and the piezoelectric layer 10, and an interdigital transducer (IDT) electrode 18 formed with the piezoelectric layer 10. In the illustrated embodiment, the IDT electrode 18 is formed over (e.g., directly on) the piezoelectric layer 10. The IDT electrode 18 can include a first layer 14, a second layer 16 over the first layer 14, and a seed layer between the first layer 14 and the piezoelectric layer 10.

The support substrate 60 can be any suitable substrate layer, such as a silicon layer, a quartz layer, a ceramic layer, a glass layer, a spinel layer, a magnesium oxide spinel layer, a sapphire layer, a diamond layer, a silicon carbide layer, a silicon nitride layer, an aluminum nitride layer, or the like. The support substrate 60 can have a relatively high acoustic impedance. An acoustic impedance of the support substrate 60 can be higher than an acoustic impedance of the piezoelectric layer 10. For instance, the support substrate 60 can have a higher acoustic impedance than an acoustic impedance of lithium niobate and a higher acoustic impedance than lithium tantalate. The acoustic impedance of the support substrate 60 can be higher than an acoustic impedance of silicon dioxide (SiO₂). The MPS SAW device 3 including the piezoelectric layer 10 on a support substrate 60 with relatively high thermal conductivity, such as silicon substrate, can achieve better thermal dissipation compared to a similar SAW resonator without the high impedance support substrate 60.

In some embodiments, the intermediate layer 62 can act as an adhesive layer. The intermediate layer 62 can include any suitable material. The intermediate layer 62 can be, for example, an oxide layer (e.g., a silicon dioxide (SiO₂) layer). In some embodiments, the intermediate layer can be a trap rich layer. In some embodiments, the trap rich layer can mitigate the parasitic surface conductivity of the support substrate 60. The trap rich layer can be formed in a number of ways, for example, by forming the surface of the support substrate 60 with amorphous or polycrystalline silicon, by forming the surface of the support substrate 60 with porous silicon, or by introducing defects into the surface of the support substrate 60 via ion implantation, ion milling, or other methods. In some embodiments, the trap rich layer can improve the electrical characteristics of the MPS SAW device 3 by increasing the depth and sharpness on the anti-resonance peak. In some embodiments, the intermediate layer 62 can have a multi-layer structure that includes an adhesion layer, a trap rich layer, and/or any other layers that can improve the performance of the MPS SAW device 3.

The TC-SAW device 4 can include a piezoelectric layer 10, an interdigital transducer (IDT) electrode 18 formed with the piezoelectric layer 10, and a temperature compensation layer 64. The temperature compensation layer (e.g., a silicon dioxide layer) can bring a temperature coefficient of frequency closer to zero.

In some embodiments, the seed layer disclosed herein may be selectively disposed in certain regions (e.g., the center region) and omitted from certain regions (e.g., the gap region and/or the bus bar region) of an IDT electrode.

Though the embodiments disclosed herein were described in connection with SAW devices that include a piezoelectric layer, the principles and advantages disclosed herein can be useful other contexts. For example, the seed layer disclosed herein may be used to form a metal layer on or over other types of substrate, such as a silicon substrate.

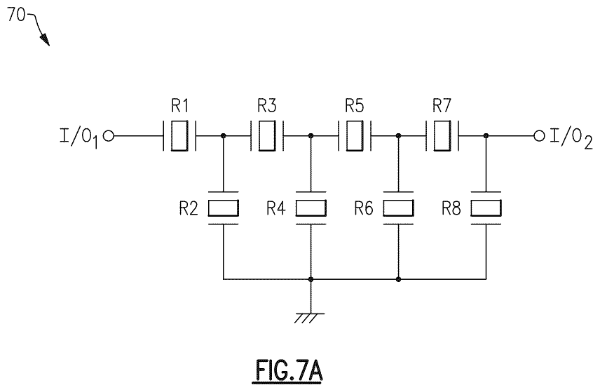

FIG. 7A is a schematic diagram of a ladder filter 70 that includes an acoustic wave resonator according to an embodiment. The ladder filter 70 is an example topology that can implement a band pass filter formed from acoustic wave resonators. In a band pass filter with a ladder filter topology, the shunt resonators can have lower resonant frequencies than the series resonators. The ladder filter 70 can be arranged to filter a radio frequency signal. As illustrated, the ladder filter 70 includes series acoustic wave resonators R1, R3, R5, and R7 and shunt acoustic wave resonators R2, R4, R6, and R8 coupled between a first input/output port I/O₁ and a second input/output port I/O₂. Any suitable number of series acoustic wave resonators can be included in a ladder filter. Any suitable number of shunt acoustic wave resonators can be included in a ladder filter. The first input/output port I/O₁ can be a transmit port and the second input/output port I/O₂ can be an antenna port. Alternatively, the first input/output port I/O₁ can be a receive port and the second input/output port I/O₂ can be an antenna port.

FIG. 7B is a schematic diagram of an example transmit filter 71 that includes surface acoustic wave resonators of a surface acoustic wave component according to an embodiment. The transmit filter 71 can be a band pass filter. The illustrated transmit filter 71 is arranged to filter a radio frequency signal received at a transmit port TX and provide a filtered output signal to an antenna port ANT. The transmit filter 71 includes series SAW resonators TS1, TS2, TS3, TS4, TS5, TS6, and TS7, shunt SAW resonators TP1, TP2, TP3, TP4, and TP5, series input inductor L1, and shunt inductor L2. Some or all of the SAW resonators TS1, TS2, TS3, TS4, TS5, TS6, and TS7 and/or TP1, TP2, TP3, TP4, and TP5 can be SAW resonators with a conductive strip for transverse mode suppression in accordance with any suitable principles and advantages disclosed herein. For instance, one or more of the SAW resonators of the transmit filter 71 can be any surface acoustic wave resonator disclosed herein. Any suitable number of series SAW resonators and shunt SAW resonators can be included in a transmit filter 71.

FIG. 7C is a schematic diagram of a receive filter 72 that includes surface acoustic wave resonators of a surface acoustic wave component according to an embodiment. The receive filter 72 can be a band pass filter. The illustrated receive filter 72 is arranged to filter a radio frequency signal received at an antenna port ANT and provide a filtered output signal to a receive port RX. The receive filter 72 includes series SAW resonators RS1, RS2, RS3, RS4, RS5, RS6, RS7, and RS7, shunt SAW resonators RP1, RP2, RP3, RP4, and RP5, and RP6, shunt inductor L2, and series output inductor L3. Some or all of the SAW resonators RS1, RS2, RS3, RS4, RS5, RS6, RS7, and RS8 and/or RP1, RP2, RP3, RP4, RP5, and RP6 can be SAW resonators with a conductive strip for transverse mode suppression in accordance with any suitable principles and advantages disclosed herein. For instance, one or more of the SAW resonators of the receive filter 72 can be any surface acoustic wave resonator disclosed herein. Any suitable number of series SAW resonators and shunt SAW resonators can be included in a receive filter 72.

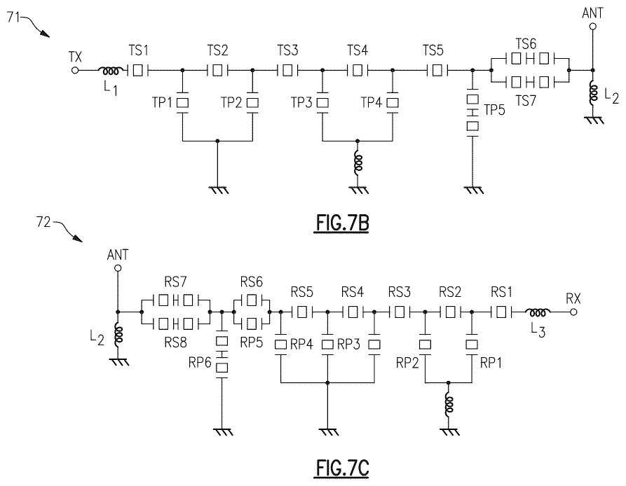

FIG. 8 is a schematic diagram of a radio frequency module 75 that includes a surface acoustic wave component 76 according to an embodiment. The illustrated radio frequency module 75 includes the SAW component 76 and other circuitry 77. The SAW component 76 can include one or more SAW resonators with any suitable combination of features of the SAW resonators and/or acoustic wave devices disclosed herein. The SAW component 76 can include a SAW die that includes SAW resonators.

The SAW component 76 shown in FIG. 8 includes a filter 78 and terminals 79A and 79B. The filter 78 includes SAW resonators. One or more of the SAW resonators can be implemented in accordance with any suitable principles and advantages of any surface acoustic wave resonator disclosed herein. The filter 78 can be a TC-SAW filter arranged as a band pass filter to filter radio frequency signals with frequencies below about 3.5 GHz in certain applications. The terminals 79A and 78B can serve, for example, as an input contact and an output contact. The SAW component 76 and the other circuitry 77 are on a common packaging substrate 80 in FIG. 8. The packaging substrate 80 can be a laminate substrate. The terminals 79A and 79B can be electrically connected to contacts 81A and 81B, respectively, on the packaging substrate 80 by way of electrical connectors 82A and 82B, respectively. The electrical connectors 82A and 82B can be bumps or wire bonds, for example. The other circuitry 77 can include any suitable additional circuitry. For example, the other circuitry can include one or more one or more power amplifiers, one or more radio frequency switches, one or more additional filters, one or more low noise amplifiers, the like, or any suitable combination thereof. The radio frequency module 75 can include one or more packaging structures to, for example, provide protection and/or facilitate easier handling of the radio frequency module 75. Such a packaging structure can include an overmold structure formed over the packaging substrate 80. The overmold structure can encapsulate some or all of the components of the radio frequency module 75.

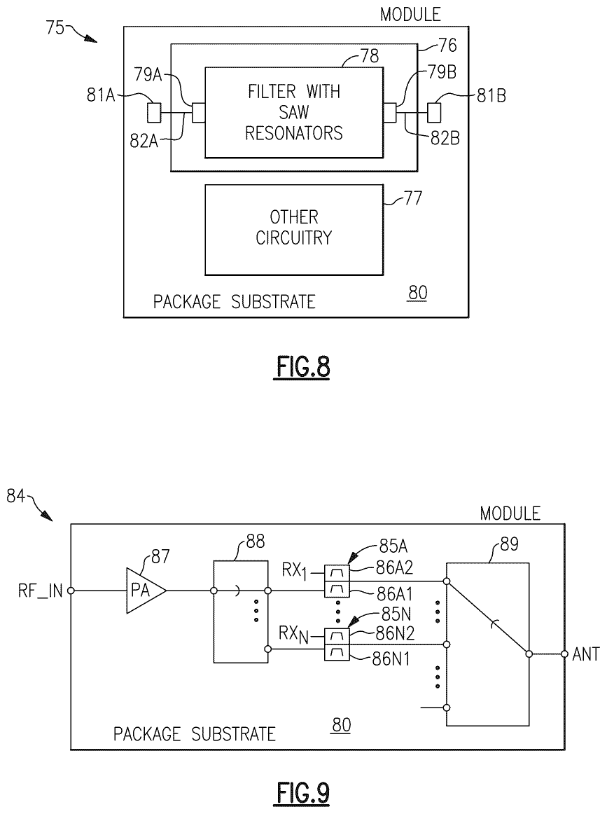

FIG. 9 is a schematic diagram of a radio frequency module 84 that includes a surface acoustic wave component according to an embodiment. As illustrated, the radio frequency module 84 includes duplexers 85A to 85N that include respective transmit filters 86A1 to 86N1 and respective receive filters 86A2 to 86N2, a power amplifier 87, a select switch 88, and an antenna switch 89. The radio frequency module 84 can include a package that encloses the illustrated elements. The illustrated elements can be disposed on a common packaging substrate 80. The packaging substrate can be a laminate substrate, for example.

The duplexers 85A to 85N can each include two acoustic wave filters coupled to a common node. The two acoustic wave filters can be a transmit filter and a receive filter. As illustrated, the transmit filter and the receive filter can each be band pass filters arranged to filter a radio frequency signal. One or more of the transmit filters 86A1 to 86N1 can include one or more SAW resonators in accordance with any suitable principles and advantages disclosed herein. Similarly, one or more of the receive filters 86A2 to 86N2 can include one or more SAW resonators in accordance with any suitable principles and advantages disclosed herein. Although FIG. 9 illustrates duplexers, any suitable principles and advantages disclosed herein can be implemented in other multiplexers (e.g., quadplexers, hexaplexers, octoplexers, etc.) and/or in switch-plexers.

The power amplifier 87 can amplify a radio frequency signal. The illustrated switch 88 is a multi-throw radio frequency switch. The switch 88 can electrically couple an output of the power amplifier 87 to a selected transmit filter of the transmit filters 86A1 to 86N1. In some instances, the switch 88 can electrically connect the output of the power amplifier 87 to more than one of the transmit filters 86A1 to 86N1. The antenna switch 89 can selectively couple a signal from one or more of the duplexers 85A to 85N to an antenna port ANT. The duplexers 85A to 85N can be associated with different frequency bands and/or different modes of operation (e.g., different power modes, different signaling modes, etc.).

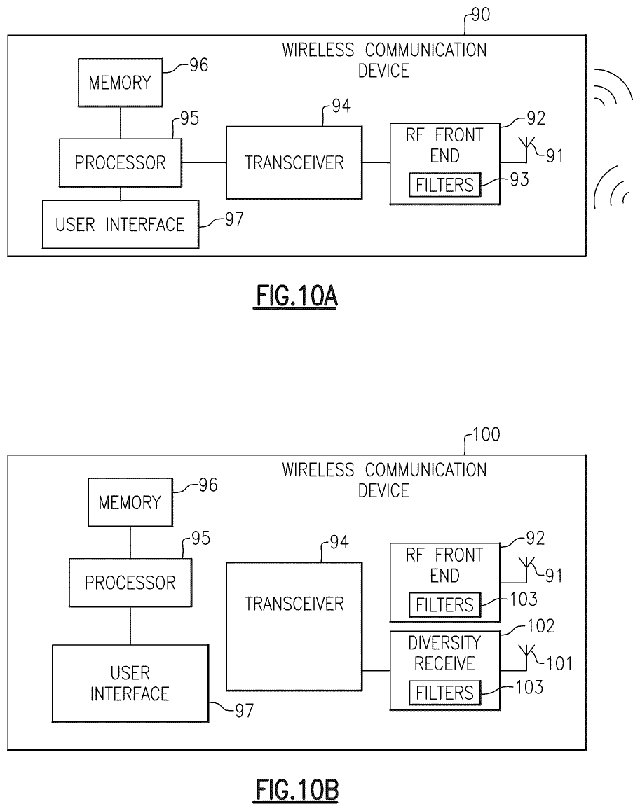

FIG. 10A is a schematic diagram of a wireless communication device 90 that includes filters 93 in a radio frequency front end 92 according to an embodiment. The filters 93 can include one or more SAW resonators in accordance with any suitable principles and advantages discussed herein. The wireless communication device 90 can be any suitable wireless communication device. For instance, a wireless communication device 90 can be a mobile phone, such as a smart phone. As illustrated, the wireless communication device 90 includes an antenna 91, an RF front end 92, a transceiver 94, a processor 95, a memory 96, and a user interface 97. The antenna 91 can transmit RF signals provided by the RF front end 92. Such RF signals can include carrier aggregation signals. Although not illustrated, the wireless communication device 90 can include a microphone and a speaker in certain applications.

The RF front end 92 can include one or more power amplifiers, one or more low noise amplifiers, one or more RF switches, one or more receive filters, one or more transmit filters, one or more duplex filters, one or more multiplexers, one or more frequency multiplexing circuits, the like, or any suitable combination thereof. The RF front end 92 can transmit and receive RF signals associated with any suitable communication standards. The filters 93 can include SAW resonators of a SAW component that includes any suitable combination of features discussed with reference to any embodiments discussed above.

The transceiver 94 can provide RF signals to the RF front end 92 for amplification and/or other processing. The transceiver 94 can also process an RF signal provided by a low noise amplifier of the RF front end 92. The transceiver 94 is in communication with the processor 95. The processor 95 can be a baseband processor. The processor 95 can provide any suitable base band processing functions for the wireless communication device 90. The memory 96 can be accessed by the processor 95. The memory 96 can store any suitable data for the wireless communication device 90. The user interface 97 can be any suitable user interface, such as a display with touch screen capabilities.

FIG. 10B is a schematic diagram of a wireless communication device 100 that includes filters 93 in a radio frequency front end 92 and a second filter 103 in a diversity receive module 102. The wireless communication device 100 is like the wireless communication device 90 of FIG. 10A, except that the wireless communication device 100 also includes diversity receive features. As illustrated in FIG. 10B, the wireless communication device 100 includes a diversity antenna 101, a diversity module 102 configured to process signals received by the diversity antenna 101 and including filters 103, and a transceiver 104 in communication with both the radio frequency front end 92 and the diversity receive module 102. The filters 103 can include one or more SAW resonators that include any suitable combination of features discussed with reference to any embodiments discussed above.

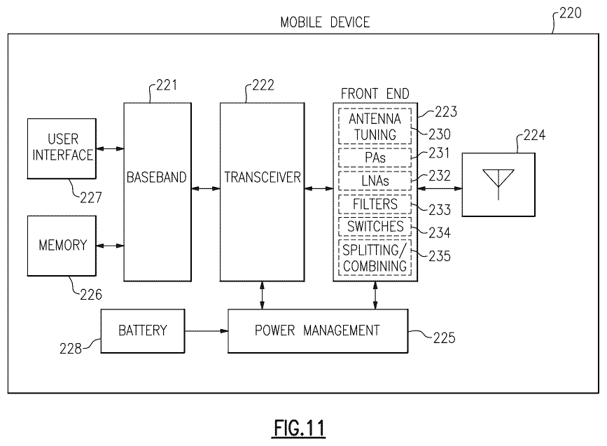

FIG. 11 is a schematic block diagram of a wireless communication device 220 that includes a filter according to an embodiment. The wireless communication device 220 can be a mobile device. The wireless communication device 220 can be any suitable wireless communication device. For instance, a wireless communication device 220 can be a mobile phone, such as a smart phone. As illustrated, the wireless communication device 220 includes a baseband system 221, a transceiver 222, a front end system 223, one or more antennas 224, a power management system 225, a memory 226, a user interface 227, and a battery 228.

The wireless communication device 220 can be used communicate using a wide variety of communications technologies, including, but not limited to, 2G, 3G, 4G (including LTE, LTE-Advanced, and/or LTE-Advanced Pro), 5G NR, WLAN (for instance, Wi-Fi), WPAN (for instance, Bluetooth and/or ZigBee), WMAN (for instance, WiMax), and/or GPS technologies.

The transceiver 222 generates RF signals for transmission and processes incoming RF signals received from the antennas 224. Various functionalities associated with the transmission and receiving of RF signals can be achieved by one or more components that are collectively represented in FIG. 11 as the transceiver 222. In one example, separate components (for instance, separate circuits or dies) can be provided for handling certain types of RF signals.

The front end system 223 aids in conditioning signals provided to and/or received from the antennas 224. In the illustrated embodiment, the front end system 223 includes antenna tuning circuitry 230, power amplifiers (PAS) 231, low noise amplifiers (LNAs) 232, filters 233, switches 234, and signal splitting/combining circuitry 235. However, other implementations are possible. The filters 233 can include one or more acoustic wave filters that include any suitable number of bulk acoustic wave devices in accordance with any suitable principles and advantages disclosed herein.

For example, the front end system 223 can provide a number of functionalities, including, but not limited to, amplifying signals for transmission, amplifying received signals, filtering signals, switching between different bands, switching between different power modes, switching between transmission and receiving modes, duplexing of signals, multiplexing of signals, or any suitable combination thereof.

In certain implementations, the wireless communication device 220 supports carrier aggregation, thereby providing flexibility to increase peak data rates. Carrier aggregation can be used for Frequency Division Duplexing (FDD) and/or Time Division Duplexing (TDD), and may be used to aggregate a plurality of carriers and/or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 224 can include antennas used for a wide variety of types of communications. For example, the antennas 224 can include antennas for transmitting and/or receiving signals associated with a wide variety of frequencies and communications standards.

In certain implementations, the antennas 224 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The wireless communication device 220 can operate with beamforming in certain implementations. For example, the front end system 223 can include amplifiers having controllable gain and phase shifters having controllable phase to provide beam formation and directivity for transmission and/or reception of signals using the antennas 224. For example, in the context of signal transmission, the amplitude and phases of the transmit signals provided to the antennas 224 are controlled such that radiated signals from the antennas 224 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 224 from a particular direction. In certain implementations, the antennas 224 include one or more arrays of antenna elements to enhance beamforming.

The baseband system 221 is coupled to the user interface 227 to facilitate processing of various user input and output (I/O), such as voice and data. The baseband system 221 provides the transceiver 222 with digital representations of transmit signals, which the transceiver 222 processes to generate RF signals for transmission. The baseband system 221 also processes digital representations of received signals provided by the transceiver 222. As shown in FIG. 11, the baseband system 221 is coupled to the memory 226 of facilitate operation of the wireless communication device 220.

The memory 226 can be used for a wide variety of purposes, such as storing data and/or instructions to facilitate the operation of the wireless communication device 220 and/or to provide storage of user information.

The power management system 225 provides a number of power management functions of the wireless communication device 220. In certain implementations, the power management system 225 includes a PA supply control circuit that controls the supply voltages of the power amplifiers 231. For example, the power management system 225 can be configured to change the supply voltage(s) provided to one or more of the power amplifiers 231 to improve efficiency, such as power added efficiency (PAE).

As shown in FIG. 11, the power management system 225 receives a battery voltage from the battery 228. The battery 228 can be any suitable battery for use in the wireless communication device 220, including, for example, a lithium-ion battery.

Any suitable principles and advantages of the surface acoustic wave devices disclosed herein can be implemented with one or more temperature compensated SAW resonators. Temperature compensated SAW resonators include a temperature compensation layer (e.g., a silicon dioxide layer) over an interdigital transducer electrode to bring a temperature coefficient of frequency closer to zero.

Packaged surface acoustic wave devices disclosed herein can include one or more surface acoustic wave resonators included in a filter arranged to filter a radio frequency signal in a fourth generation (4G) Long Term Evolution (LTE) operating band. Packaged surface acoustic wave devices disclosed herein can include one or more surface acoustic wave resonators included in a filter arranged to filter a radio frequency signal in a fifth generation (5G) New Radio (NR) operating band within Frequency Range 1 (FR1). FR1 can be from 410 megahertz (MHz) to 7.125 gigahertz (GHz), for example, as specified in a current 5G NR specification. Packaged surface acoustic wave devices disclosed herein can include one or more surface acoustic wave resonators included in a filter with a passband corresponding to both a 4G LTE operating band and a 5G NR operating band within FR1.

Any of the embodiments disclosed herein can be combined. Any of the embodiments described above can be implemented in association with a radio frequency system and/or mobile devices such as cellular handsets. The principles and advantages of the embodiments can be used for any systems or apparatus that could benefit from any of the embodiments described herein. The teachings herein are applicable to a variety of systems. Although this disclosure includes example embodiments, the teachings described herein can be applied to a variety of structures. Any of the principles and advantages discussed herein can be implemented in association with RF circuits configured to process signals in a frequency range from about 30 kHz to 300 GHz, such as in a frequency range from about 450 MHz to 8.5 GHZ, a frequency range from about 450 MHz to 2.5 GHZ, or a frequency range from about 450 MHz to 3 GHZ.

Aspects of this disclosure can be implemented in various electronic devices. Examples of the electronic devices can include, but are not limited to, consumer electronic products, parts of the consumer electronic products such as semiconductor die and/or packaged radio frequency modules, electronic test equipment, uplink wireless communication devices, personal area network communication devices, etc. Examples of the consumer electronic products can include, but are not limited to, a mobile phone such as a smart phone, a wearable computing device such as a smart watch or an ear piece, a telephone, a television, a computer monitor, a computer, a router, a modem, a hand-held computer, a laptop computer, a tablet computer, a personal digital assistant (PDA), a microwave, a refrigerator, a vehicular electronics system such as an automotive electronics system, a stereo system, a DVD player, a CD player, a digital music player such as an MP3 player, a radio, a camcorder, a camera such as a digital camera, a portable memory chip, a washer, a dryer, a washer/dryer, a peripheral device, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. An acoustic wave device comprising:
a piezoelectric layer; and
an interdigital transducer electrode formed with the piezoelectric layer, the interdigital transducer electrode including a first layer, a second layer over the first layer, and a seed layer between the first layer and the piezoelectric layer, a combination of the first layer and the seed layer having a resistivity lower than a resistivity of the first layer alone.

2. The acoustic wave device of claim 1 wherein the first layer has a stiffness that is greater than a stiffness of the second layer.

3. The acoustic wave device of claim 1 wherein the seed layer has a stiffness that is greater than a stiffness of the second layer.

4. The acoustic wave device of claim 1 wherein the first layer and the seed layer include materials from the same group.

5. The acoustic wave device of claim 4 wherein the first layer includes molybdenum, tungsten, or chromium, and the seed layer includes one of molybdenum, tungsten, or chromium not used for the first layer.

6. The acoustic wave device of claim 4 wherein the first layer includes molybdenum, the second layer includes aluminum, and the seed layer includes tungsten.

7. The acoustic wave device of claim 1 wherein the seed layer has a thickness in a range of 5 nm to 50 nm.

8. The acoustic wave device of claim 7 wherein the seed layer has a thickness in a range of 5 nm to 20 nm.

9. The acoustic wave device of claim 1 wherein the seed layer has a thickness less than 10% of a thickness of the first layer.

10. The acoustic wave device of claim 1 wherein the seed layer has a thickness less than 5% of a total thickness of the interdigital transducer electrode.

11. An acoustic wave device comprising:
a piezoelectric layer; and
an interdigital transducer electrode formed with the piezoelectric layer, the interdigital transducer electrode including a first layer, a second layer over the first layer, and a tungsten seed layer between the first layer and the piezoelectric layer.

12. The acoustic wave device of claim 11 wherein the first layer includes molybdenum.

13. The acoustic wave device of claim 11 wherein the seed layer has a thickness in a range of 5 nm to 50 nm.

14. The acoustic wave device of claim 13 wherein the seed layer has a thickness in a range of 5 nm to 20 nm.

15. The acoustic wave device of claim 11 wherein the seed layer has a thickness less than 10% of a thickness of the first layer.

16. The acoustic wave device of claim 11 wherein the seed layer has a thickness less than 5% of a total thickness of the interdigital transducer electrode.

17. An acoustic wave device configured to generate a surface acoustic wave having a wavelength L, the acoustic wave device comprising:
a piezoelectric layer; and
an interdigital transducer electrode formed with the piezoelectric layer, the interdigital transducer electrode including a first layer, a second layer over the first layer, and a seed layer between the first layer and the piezoelectric layer, the first layer having a first thickness in a range of 0.01 L to 0.075 L, the second layer having a second thickness in a range of 0.05 L to 0.2 L, and the seed layer having a third thickness in a range of 5 nm to 50 nm.

18. The acoustic wave device of claim 17 wherein the first layer has a stiffness that is greater than a stiffness of the second layer.

19. The acoustic wave device of claim 17 wherein the seed layer has a stiffness that is greater than a stiffness of the second layer.

20. The acoustic wave device of claim 17 wherein the first layer and the seed layer include materials from the same group.
